(19) United States
(12) Patent Application Publication
(10) Pub. No.: US 2026/0310102 A1
(43) Pub. Date: Oct. 8, 2026

(54) SYSTEM FOR AND METHOD OF CALIBRATING MEASUREMENT OF DUV LASER BEAM SPECTRAL PROPERTIES

(71) Applicant: Cymer, LLC, San Diego, CA (US)

(72) Inventors: Thomas Patrick Duffey, San Diego, CA (US); Zhong Quan Zhao, San Diego, CA (US); Mingchen Liu, Pasadena, CA (US)

(21) Appl. No.: 19/481,455

(22) PCT Filed: May 30, 2024
(86) PCT No.: PCT/IB2024/055270

§ 371 Date: Nov. 4, 2025

Related U.S. Application Data
(60) Provisional application No. 63/471,045, filed on Jun. 5, 2023.
(60) Provisional application No. 63/647,132, filed on May 14, 2024.

(51) Int. Cl. G03F 7/00

(52) U.S. Cl. CPC G03F 7/70575; G03F 7/7085

(57) ABSTRACT

A system for and method of measuring one or more spectral properties such as wavelength and/or bandwidth of a beam of deep ultraviolet excimer laser radiation in which an absolute reference is used to calibrate instrumentation for measuring the one or more spectral properties, the absolute reference being generated using Doppler free spectroscopy. Also disclose are systems and methods in which an isotopically concentrated material is used.

### CROSS-REFERENCE TO RELATED APPLICATIONS

This application claims priority of U.S. Application No. 63/471,045, filed on Jun. 5, 2023, titled SYSTEM FOR AND METHOD OF CALIBRATING MEASUREMENT OF DUV LASER BEAM SPECTRAL PROPERTIES and U.S. Application No. 63/647,132, filed on May 14, 2024, titled SYSTEM FOR AND METHOD OF CALIBRATING MEASUREMENT OF DUV LASER BEAM SPECTRAL PROPERTIES, which are incorporated herein by reference in their entirety.

### FIELD

The disclosed subject matter relates to a system for and method of measuring one or more spectral properties, for example, bandwidth or wavelength, of a deep ultraviolet (DUV) radiation beam.

### BACKGROUND

Photolithography is a process by which circuitry is patterned on a semiconductor substrate such as a silicon wafer. A photolithography radiation source provides DUV radiation (radiation having wavelengths in a range of about 100 nanometers (nm) to about 400 nm) used to expose a photoresist on the wafer. Often, the radiation source is a laser source and the radiation is a pulsed laser beam. The radiation beam is passed through a beam delivery unit, then through or reflected by a reticle or a mask, and then projected onto a silicon wafer coated with photoresist. In this way, a chip design pattern is formed in the photoresist, and then in the silicon wafer by etching. The photoresist is then removed by cleaning.

In many systems that produce a laser beam (such as a laser generator) or employ a laser beam (such as a photolithography system), there is an optical train that includes one or more optical components (such as mirrors, gratings, prisms, optical switches, filters, etc.). Optical components in the optical train may, wholly or partially, reflect, process, filter, modify, focus, expand, etc. the laser beam to obtain one or more desired laser beam outputs.

In such systems it is generally desired to measure and control various spectral properties of the DUV radiation beam such as its wavelength (e.g., center line wavelength) and its bandwidth (e.g., full width half maximum (FWHM) bandwidth). A spectral analysis module is used to measure spectral properties of the radiation beam, and such measured spectral properties are then used to control aspects of the radiation beam.

It would be advantageous to improve the accuracy of the measurement of the radiation beam spectral properties. It is in this context that the need for the subject matter of the present disclosure arises.

### SUMMARY

The following presents a succinct summary of one or more embodiments in order to promote a basic understanding of the presently disclosed subject matter. This summary is not an extensive overview of all contemplated embodiments and is not intended to identify as key or critical any elements of any embodiments nor delineate the scope of any or all embodiments. Its sole purpose is to present some concepts relating to one or more embodiments in a streamlined form as a prelude to the more detailed description that is presented later.

According to an aspect of an embodiment there is disclosed a metrology system for measuring a spectral property of a beam of excimer laser radiation, the metrology system comprising a beam separator for separating a beam of metrology radiation from the beam of excimer laser radiation, a source of a beam of calibration radiation, a measuring module arranged to receive the beam of metrology radiation and configured to measure a spectral property of the beam of metrology radiation and generate a measurement signal indicative of the spectral property and a calibration module arranged to receive either the beam of metrology radiation or the beam of calibration radiation as an input beam of radiation.

The calibration module includes a material having a known energy transition at a specified wavelength, an optical arrangement configured to divide the beam of input radiation into a pump beam and first and second probe beams, direct the pump beam through the material along a first path in a first direction, and direct the first probe beam through the material along the first path in a second direction opposite the first direction and the second probe beam through the material along a second path in the second direction, and a detector configured to receive the first probe beam after the first probe beam has traversed the first path, receive the second probe beam after the second probe beam has traversed the second path, measure a property of the first probe beam and a property of the second probe beam as a wavelength of the beam of input radiation is caused to vary through a range of wavelengths including the specified wavelength, obtain a difference between the property of the first probe beam and the property of the second probe beam, and generate a first differential signal based on the difference between the property of the first probe beam and the property of the second probe beam when the input beam comprises the metrology radiation and a second differential signal based on the difference between the property of the first probe beam and the property of the second probe beam when the input beam comprises the calibration radiation.

The metrology system also comprises a control system arranged to receive the first differential signal and the second differential signal and adapted to generate an absolute reference signal based on the first differential signal and the second differential signal.

The control system may be adapted to calibrate the measurement of the spectral property based on the absolute reference signal. The pump beam may saturate the material along the first path.

The metrology system may further comprise a source for the calibration radiation.

The spectral property may be a center wavelength of the laser radiation. The spectral property may be a bandwidth of the laser radiation.

The material may be platinum vapor. The known energy transition may be the atomic absorption transition of platinum atoms at 193.4369 nanometers. The known energy transition may be the atomic absorption transition of iron atoms at 248.3271 nanometers.

The optical arrangement may comprise a first beam splitter arranged to divide the first probe beam and second probe beam from the beam of input radiation and to direct the first probe beam along the first path and the second probe beam along the second path and a plurality of mirrors arranged to direct a remaining portion of the beam of input radiation after the first probe beam and second probe beam have been divided out along the first path in the first direction.

According to another aspect of an embodiment there is disclosed a system for measuring a spectrum of an incident beam from a laser source, the spectrum exhibiting a first amount of Doppler broadening, the system comprising an absorption cell containing an absorptive medium, a first beam splitter having two reflective surfaces that generate a first beam and a second beam from the incident beam, the first beam and the second beam passing through the absorptive medium after reflection, a second beam splitter positioned and oriented to generate a third beam from the incident beam, the third beam being directed to propagate in a direction opposite to and colinear with a direction of propagation of the second beam, and a differential detector configured to receive the first beam and the second beam and generate a differential transition profile of the incident beam as a wavelength of the incident beam is varied through a range of wavelength values, the differential transition profile having a second amount of Doppler broadening, the second amount of Doppler broadening being less than the first amount of Doppler broadening, wherein the absorptive medium comprises a material having one or more transition lines in the range of wavelength values.

The absorptive medium may comprise platinum vapor.

According to another aspect of an embodiment there is disclosed a metrology method comprising receiving a beam of input radiation, dividing the beam of input radiation into a pump beam and first and second probe beams, directing the pump beam through a material having a known energy transition at a specified wavelength along a first path in a first direction to saturate the material along the first path, directing the first probe beam through the material along the first path in a second direction the opposite of the first direction, directing the second probe beam through the material along a second path in the second direction, receiving the first probe beam after the first probe beam has traversed the first path, receiving the second probe beam after the second probe beam has traversed the second path, measuring a property of the first probe beam and a property of the second probe beam as a wavelength of the beam of input radiation is varied though a range of wavelengths including the specified wavelength, measuring a difference between the property of the first probe beam and the property of the second probe beam, generating a transition profile based on a difference between the spectral property of the first probe beam and the spectral property of the second probe beam, generating an absolute reference based at least in part on the transition profile, and calibrating a measurement of a spectral property of an excimer laser beam based at least in part on the absolute reference signal.

The input radiation may comprise either metrology radiation separated from an excimer laser beam or calibration radiation from a calibration radiation source, the transition profile being a convolved transition profile when the input radiation comprises the metrology radiation or an intrinsic transition profile when the input radiation comprises the calibration radiation, and generating an absolute reference based at least in part on the transition profile may comprise generating an absolute reference based at least in part on the convolved transition profile and the intrinsic transition profile.

The metrology method may further comprise generating the input radiation using a single wavelength laser source.

The spectral property may be a center wavelength of the laser radiation. The spectral property may be a bandwidth of the calibration laser radiation.

The material may be platinum vapor. The known energy transition may be the atomic absorption transition of platinum atoms at 193.4369 nanometers. The material may be iron vapor. The known energy transition may be the atomic absorption transition of iron atoms at 248.3271 nanometers.

According to another aspect of an embodiment there is disclosed a metrology method comprising performing a measurement of a center wavelength of a deep ultraviolet excimer laser beam, generating an absolute wavelength reference using Doppler-free spectroscopy, and using the absolute wavelength reference to calibrate the measurement.

According to another aspect of an embodiment there is disclosed a metrology method comprising performing a measurement of a bandwidth of a deep ultraviolet excimer laser beam, generating an absolute bandwidth reference using Doppler-free spectroscopy, and using the absolute wavelength reference to calibrate the measurement.

According to another aspect of an embodiment there is disclosed a metrology system for measuring a spectral property of a beam of excimer laser radiation, the metrology system comprising a beam separator for separating a beam of metrology radiation from the beam of excimer laser radiation, a source of a beam of calibration radiation, a measuring module arranged to receive the beam of metrology radiation and configured to measure a spectral property of the beam of metrology radiation and generate a measurement signal indicative of the spectral property, and a calibration module arranged to receive either the beam of metrology radiation or the beam of calibration radiation as an input beam of radiation.

The calibration module includes a vapor of an elemental material having a concentrated proportion of an isotope of the elemental material, the isotope having a known energy transition at a specified wavelength, an optical arrangement configured to divide the beam of input radiation into a pump beam and first and second probe beams, direct the pump beam through the material along a first path in a first direction, and direct the first probe beam through the material along the first path in a second direction the opposite of the first direction and the second probe beam through the material along a second path in the second direction, and a detector configured to receive the first probe beam after the first probe beam has traversed the first path, receive the second probe beam after the second probe beam has traversed the second path, measure a property of the first probe beam and a property of the second probe beam as a wavelength of the beam of input radiation is caused to vary through a range of wavelengths including the specified wavelength, obtain a difference between the property of the first probe beam and the property of the second probe beam, and generate a first differential signal based on the difference between the property of the first probe beam and the property of the second probe beam when the input beam comprises the beam of metrology radiation and a second differential signal based on the difference between the property of the first probe beam and the property of the second probe beam when the input beam comprises the beam of calibration radiation

The metrology system also includes a control system arranged to receive the first differential signal and the second differential signal and adapted to generate an absolute reference signal based on the first differential signal and the second differential signal.

The control system may be adapted to calibrate the measurement of the spectral property based on the absolute reference signal. The spectral property may be a center wavelength of the beam of metrology radiation. The spectral property may be a bandwidth of the beam of metrology radiation.

The elemental material may comprise platinum. The elemental material may comprise iron. The elemental material may comprise carbon. The elemental material may comprise arsenic. The elemental material may comprise aluminum. At least 90% of the elemental material may comprise the isotope, i.e., the isotope may make up at least 90% of the elemental material by weight.

According to another aspect of an embodiment there is disclosed a system for measuring a spectrum of an incident beam from a laser source, the spectrum exhibiting a first amount of Doppler broadening, the system comprising an absorption cell containing an absorptive medium, a first beam splitter configured to generate a first beam and a second beam from the incident beam, the first beam and the second beam passing through the absorptive medium after reflection, a second beam splitter positioned and oriented to generate a third beam from the incident beam, the third beam being directed to propagate in a direction opposite to and colinear with a direction of propagation of the second beam, and a differential detector configured to receive the first beam and the second beam and generate a differential transition profile of the incident beam as a wavelength of the incident beam is varied through a range of wavelength values, the differential transition profile having a second amount of Doppler broadening, the second amount of Doppler broadening being less than the first amount of Doppler broadening, wherein the absorptive medium comprises a vapor of an elemental material having a concentrated proportion of an isotope of the elemental material, the isotope having a known energy transition at a specified wavelength.

The elemental material may comprise platinum. The elemental material may comprise iron. The elemental material may comprise carbon. The elemental material may comprise arsenic. The elemental material may comprise aluminum. At least 90% of the elemental material may comprise the isotope, i.e., the isotope may make up at least 90% of the elemental material by weight.

According to another aspect of an embodiment there is disclosed a metrology method comprising receiving a beam of input radiation, dividing the beam of input radiation into a pump beam and first and second probe beams, directing the pump beam through a vapor of an elemental material having a concentrated proportion of an isotope of the elemental material, the isotope having a known energy transition at a specified wavelength, along a first path in a first direction to saturate the material along the first path, directing the first probe beam through the vapor of the elemental material along the first path in a second direction opposite the first direction, directing the second probe beam through the vapor of the elemental material along a second path in the second direction, receiving the first probe beam after the first probe beam has traversed the first path, receiving the second probe beam after the second probe beam has traversed the second path, measuring a spectral property of the first probe beam and a spectral property of the second probe beam as a wavelength of the beam of input radiation is varied though a range of wavelengths including the specified wavelength, measuring a difference between the property of the first probe beam and the property of the second probe beam, generating a transition profile based on a difference between the spectral property of the first probe beam and the spectral property of the second probe beam, generating an absolute reference based at least in part on the transition profile, and calibrating a measurement of a spectral property of an excimer laser beam based at least in part on the absolute reference signal. At least 90% of the elemental material may comprise the isotope, i.e., the isotope may make up at least 90% of the elemental material by weight.

According to another aspect of an embodiment there is disclosed a metrology method comprising performing a measurement of a center wavelength of a deep ultraviolet excimer laser beam, generating an absolute wavelength reference using an elemental material having a concentrated proportion of an isotope of the elemental material, the isotope having a known energy transition at a specified wavelength, and using the absolute wavelength reference to calibrate the measurement. At least 90% of the elemental material may comprise the isotope, i.e., the isotope may make up at least 90% of the elemental material by weight.

According to another aspect of an embodiment there is disclosed a metrology method comprising performing a measurement of a bandwidth of a deep ultraviolet excimer laser beam, generating an absolute bandwidth reference using an elemental material having a concentrated proportion of an isotope of the elemental material, the isotope having a known energy transition at a specified wavelength, and using the absolute wavelength reference to calibrate the measurement. At least 90% of the elemental material may comprise the isotope, i.e., the isotope may make up at least 90% of the elemental material by weight.

According to another aspect of an embodiment there is disclosed a galvatron comprising an anode and a cathode, the cathode comprising an elemental material having a concentrated proportion of an isotope of the elemental material, the isotope having a known energy transition at a specified wavelength. At least 90% of the elemental material may comprise the isotope, i.e., the isotope may make up at least 90% of the elemental material by weight.

Further embodiments, features, and advantages of the subject matter of the present disclosure, as well as the structure and operation of the various embodiments, are described in detail below with reference to the accompanying drawings.

### BRIEF DESCRIPTION OF THE DRAWINGS

The accompanying drawings, which are incorporated herein and form part of the specification, illustrate the presently disclosed subject matter and, together with the description, further serve to explain the principles of the presently disclosed subject matter and to enable a person skilled in the relevant art(s) to make and use the presently disclosed subject matter.

FIG. 1 is a functional block diagram, not to scale, of an overall broad conception of a photolithography system.

FIG. 2 is a functional block diagram, not to scale, of an overall broad conception of an illumination system such as might be used in the photolithography system of FIG. 1.

FIG. 3 is a functional block diagram, not to scale, of overall broad conception of a metrology system such as might be used in the photolithography system of FIG. 1.

FIG. 4 is a functional block diagram, not to scale, of a calibration system for a metrology system such as might be used in a DUV radiation source.

FIG. 5 is a functional block diagram, not to scale, of an arrangement for generating transition profiles for a calibration system such as might be used in a DUV radiation source.

FIGS. 6A and 6B are graphical representations of transition profiles in an arrangement for generating an absolute reference signal for a calibration system such as might be used in a DUV radiation source according to an aspect of an embodiment.

FIG. 7 is a functional block diagram, not to scale, of an arrangement for generating transition profiles for a calibration system in a DUV radiation source according to an aspect of an embodiment.

FIG. 8 is a flow chart for a method of calibrating a metrology system for a DUV radiation source according to an aspect of an embodiment.

FIG. 9 is a diagram of procedures for performing steps in a method of calibrating a metrology system for a DUV radiation source according to an aspect of an embodiment.

FIG. 10 is a diagram of procedures for performing a step in a method of calibrating a metrology system for a DUV radiation source according to an aspect of an embodiment.

FIG. 11A is a diagram of a galvatron according to an aspect of an embodiment.

FIG. 11B is an end-on view of the galvatron of FIG. 11A taken along line BB.

Further features and advantages of the presently disclosed subject matter, as well as the structure and operation of various embodiments of the presently disclosed subject matter, are described in detail below with reference to the accompanying drawings. It is noted that the scope of the presently disclosed subject matter is not limited to the specific embodiments described herein. Such embodiments are presented herein for illustrative purposes only. Additional embodiments will be apparent to persons skilled in the relevant art based on the teachings presented herein.

### DETAILED DESCRIPTION

Various embodiments are now described with reference to the drawings, wherein like reference numerals are used to refer to like elements throughout. In the following description, for purposes of explanation, numerous specific details are set forth in order to promote a thorough understanding of one or more embodiments. It may be evident in some or all instances, however, that any embodiment described below can be practiced without adopting the specific design details associated with it below. In other instances, well-known structures and devices are shown in block diagram form in order to facilitate description of one or more embodiments. This summary is not an extensive overview of all contemplated embodiments and is not intended to single out as key or critical any elements of any embodiments nor delineate the scope of any or all embodiments.

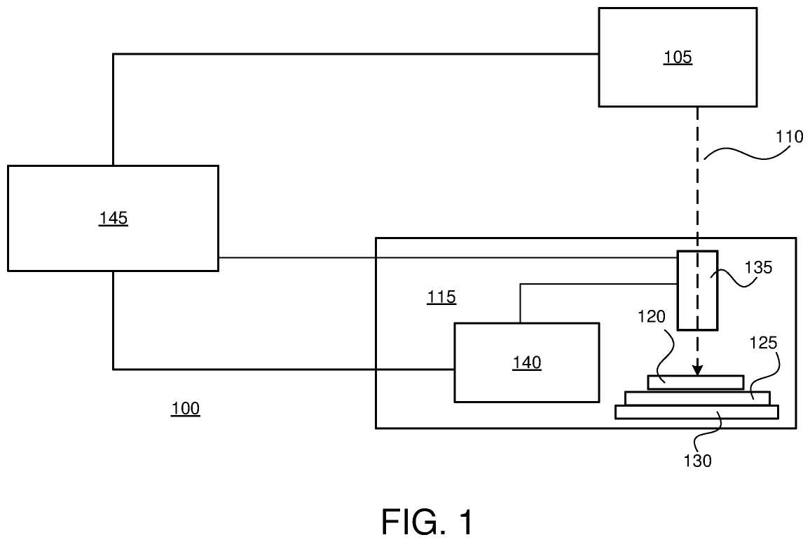

Systems such as those described herein may render benefits in a wide range of applications and implementations. For the sake of having a specific nonlimiting example to facilitate description, one such application is in semiconductor photolithography. FIG. 1 shows a photolithography system 100 that includes an illumination system 105. As described more fully below, the illumination system 105 includes a radiation source that produces a pulsed radiation beam 110 and directs it to a photolithography exposure apparatus 115 such as a scanner that patterns microelectronic features on a wafer 120. The wafer 120 is placed on a wafer table 125 constructed to hold wafer 120 and connected to a positioner 130 configured to accurately position the wafer 120 in accordance with certain parameters.

The pulsed radiation beam 110 may have a wavelength in the DUV range. The scanner 115 includes an optical arrangement 135 having, for example, one or more condenser lenses, a mask, and an objective arrangement. The mask is movable along one or more directions, such as along an optical axis of the pulsed radiation beam 110 or in a plane that is perpendicular to the optical axis. The objective arrangement includes a projection lens and enables an image transfer to occur from the mask to photoresist on the wafer 120. The illumination system 105 adjusts the range of angles for the pulsed radiation beam 110 impinging on the mask. The illumination system 105 also homogenizes (makes uniform) the intensity distribution of the pulsed radiation beam 110 across the mask.

The scanner 115 can include, among other features, a lithography controller 140 that controls how layers are printed on the wafer 120. The lithography controller 140 may include a memory that stores information such as process recipes that determine the parameters of the beam including a length of the exposure on the wafer 120 based on, for example, the mask used, as well as other factors that affect exposure. During lithography, a burst of pulses of the pulsed radiation beam 110 illuminates the same area of the wafer 120 to constitute an illumination dose.

The photolithography system 100 also preferably includes a control system 145. In general, the control system 145 includes one or more of digital electronic circuitry, computer hardware, firmware, and software. The control system 145 can be centralized or be partially or wholly distributed throughout the photolithography system 100.

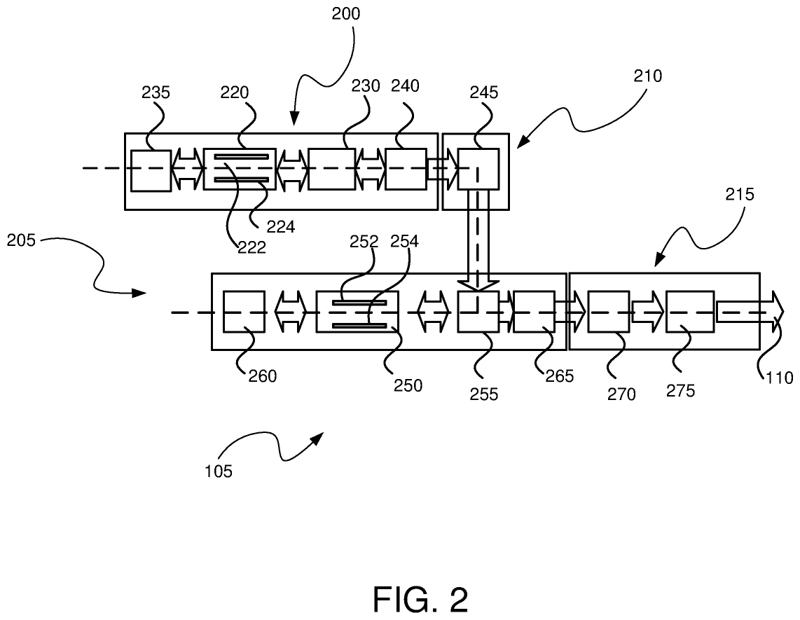

FIG. 2 shows a pulsed laser source that produces a pulsed laser beam as the radiation beam 110 as an example of an illumination system 105. FIG. 2 shows a two-chamber laser system as a nonlimiting example but it will be understood that the principles explained herein are equally applicable to a single chamber laser system or a laser system having more than two chambers. The gas discharge laser system may include, e.g., a solid state or gas discharge master oscillator (“MO”) seed laser system 200, an amplification stage, e.g., a power ring amplifier (“PRA”) stage 205, relay optics 210, and laser system output subsystem 215. The seed system 200 may include, e.g., an MO chamber 220 which includes a pair of electrodes 222 and 224.

The MO seed laser system 200 may also include a master oscillator output coupler (“MO OC”) 230, which may comprise a partially reflective mirror, forming an MO discharge chamber 220 with an oscillator cavity, defined in part by a reflective grating (not shown) in a line narrowing module (“LNM”) 235, that oscillates to generate the seed laser output pulse. The MO seed laser system 200 may also include a line-center analysis module (“LAM”) 240. A MO wavefront engineering box (“WEB”) 245 may serve to redirect the output of the MO seed laser system 200 toward the amplification stage 205, and may include, e.g., a multi prism beam expander (not shown) and an optical delay path (not shown).

The amplification stage 205 may include, e.g., a PRA discharge chamber 250, which also may be an oscillator, e.g., formed by seed beam injection and output coupling optics (not shown) that may be incorporated into a PRA WEB 255. The beam may be redirected back through the gain medium in the PRA discharge chamber 250 by a beam reverser (“BR”) 260. The PRA WEB 255 may incorporate a partially reflective input/output coupler (not shown) and a maximally reflective mirror for the nominal operating wavelength (e.g., at around 193 nm for an ArF system and around 248 nm for a KrF system) and one or more prisms. The PRA discharge chamber 250 may also include a pair of electrodes 252 and 254.

The laser output radiation beam of pulses from the PRA discharge chamber 250 then passes through the PRA WEB 255. A bandwidth analysis module (“BAM”) 265 is arranged to receive the output laser radiation beam of pulses from the PRA WEB 255 and divert a portion of the radiation beam for metrology purposes, e.g., to measure one or more of the output wavelength, bandwidth, and pulse energy. The remainder of the radiation beam then passes to an optical pulse stretcher (“OPuS”) 270 and an autoshutter, in this case a combined autoshutter metrology module (“CASMM”) 275, which may also be the location of a pulse energy meter. One purpose of the OPuS 270 may be, e.g., to convert a single output laser pulse into a pulse train. Secondary pulses created from the original single output pulse may be delayed with respect to each other. By distributing the original laser pulse energy into a train of secondary pulses, the effective pulse length of the laser can be expanded and at the same time the peak pulse intensity reduced. The OPuS 270 may accordingly be arranged to receive the laser beam from the BAM 265 and direct its output to the CASMM 275. One of ordinary skill in the art will appreciate that this ordering of components and modules may be altered.

The PRA discharge chamber 250 and the MO discharge chamber 220 are configured as chambers in which electrical discharges between the electrodes cause lasing gas discharges in a lasing gas to create an inverted population of high energy molecules or excimers, including, e.g., ArF, KrF, F₂, XeF, and/or XeCl, to produce relatively broad band radiation that may be line narrowed to a relatively very narrow bandwidth and center wavelength selected in the LNM 235.

The LAM 240 and the BAM 265 thus measure center wavelength and bandwidth, respectively. Either of these can be regarded as a metrology system. The metrology systems measure or sense the actual spectral feature or property (such as a bandwidth or the wavelength) of the radiation beam during operation of the optical source by estimating a value of a metric from a measured optical spectrum. An operator or an automated system (for example, the control system 185) can use the measured or sensed bandwidth of the radiation beam to adjust the properties of the optical source 105 (for example, by sending a signal to a spectral property selection system such as the LNM to thereby adjust the optical spectrum (and the spectral features) of the radiation beam. The control system 185 receives the output of the metrology system and analyzes the sensed spectral profile and estimates one or more spectral features of the radiation beam based on this analysis.

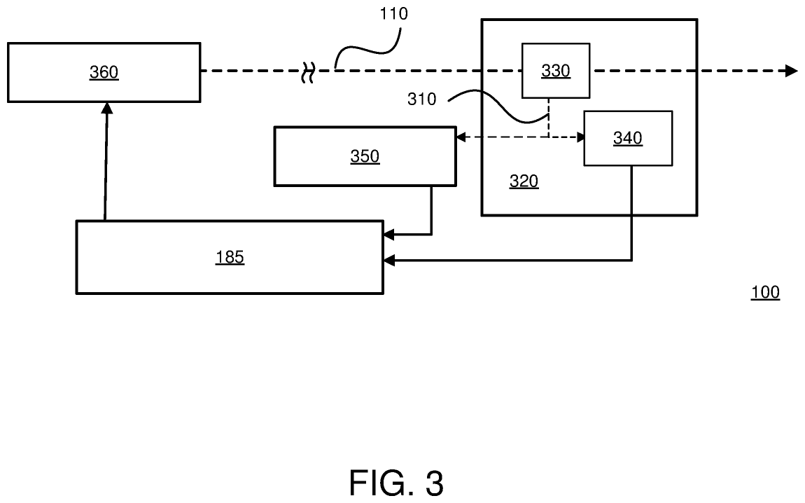

FIG. 3 is a schematic diagram of selected components of a metrology system 100 including a spectral property controller 360. Various methods are well known for wavelength tuning of lasers. Typically the tuning takes place in the LNM. A typical technique used for line narrowing and tuning of excimer lasers is to provide a window at the back of the discharge cavity through which a portion of the laser beam passes into the LNM. There, the portion of the beam is expanded and directed to a grating which reflects a narrow selected portion of the laser's broader spectrum back into the discharge chamber where it is amplified. The laser is typically tuned by changing the angle at which the beam encounters the grating. This may be done by adjusting the position of the grating or providing a mirror adjustment in the beam path. The adjustment of the grating position or the mirror position may be made by a mechanism which may be referred to as a wavelength adjustment mechanism. For many applications it is important that the laser not only be finely tunable but also that the wavelength of the beam be set to a precise absolute value, with a very small deviation.

The spectral property controller 360 is thus arranged to operate on the radiation beam 110 to control a spectral characteristic of the radiation beam 110. Then, at a position optically downstream of the spectral property controller 360, a metrology system 320 is positioned to receive and pick off a portion of the radiation beam 110 using a beam divider 330 to create a metrology beam 310. The metrology beam 310 propagates to a measuring device 340 which measures the spectral property of interest and generates a signal indicative of the measured property which is supplied, for example, to the control system 185 which uses the signal to control the spectral property controller 360. These and other details of this arrangement are described in U.S. Pat. No. 9,983,060 (the '060 patent), issued May 29, 2018, and titled “Calibration of a Spectral Analysis Module.”

All patent applications, patents, and printed publications cited herein are incorporated herein by reference in their entireties, except for any definitions, subject matter disclaimers, or disavowals, and except to the extent that the incorporated material is inconsistent with the express disclosure herein, in which case the language in this disclosure controls.

As also shown in FIG. 3 the measuring device 340 receives the radiation beam 310 that is picked off from the radiation beam 110 by the beam separator or divider 330. The beam separator 330 directs the radiation beam 310 (which is a first portion or percentage of the radiation beam 110) into the measuring device 340 and permits transmission of a second portion or percentage of the radiation beam 110 toward the exposure apparatus. In some implementations, the majority of the radiation beam 110 is directed in the second portion toward the exposure apparatus 115. For example, the beam separator 330 directs a fraction (for example, 1-2%) of the radiation beam 110 into the measuring device 340 and thus the radiation beam 310 has about 1-2% of the power of the radiation beam 110. The beam separator 330 can be, for example, a beam splitter. The measuring device 340 measures the spectral property or properties (such as the bandwidth and/or the wavelength) of the radiation beam 110.

Spectral properties of the radiation beam include any aspect or representation of its optical spectrum. For example, bandwidth and center wavelength are spectral properties. The bandwidth of the radiation beam is a measure of the width of its optical spectrum, and this width can be given in terms of wavelength or frequency of the laser radiation. Any suitable mathematical construction (for example, metric) related to the details of its optical spectrum can be used to estimate a value that characterizes the bandwidth of the radiation beam.

Also as described in the '060 patent, for various reasons the measurement made by the metrology system 320 may be inaccurate. For example, during operation, the accuracy of the metrology system 320 can deteriorate due to various causes. Overtime, optical components (such as an etalon or a lens) within the metrology system 320 can degrade due to interaction between these optical components and the radiation beam 110. The finesse of the etalon within the metrology system 320 can degrade upon repeated interaction between the etalon and the radiation beam 310. These and other causes compromise the accuracy of the measurements made by the metrology system 320, thus impeding accurate determination of the spectral features of the radiation beam 110 and so to control the spectral features of the radiation beam 110 at the wafer 120. It is thus necessary to provide some system for calibrating the measurements made by the metrology system 320.

In order to improve the accuracy of measurements of a spectral property such as the bandwidth within the metrology system 320, a calibration apparatus 350 also receives the metrology beam 310. The calibration apparatus 350 is configured to provide an absolute reference for the spectral property of the radiation beam 110 that is to be measured. For example, the calibration apparatus 350 can provide an absolute reference for the bandwidth of the radiation beam 110 and this can be referred to as an absolute bandwidth reference (ABR). As another example, the calibration apparatus 350 can provide an absolute reference for the wavelength of the radiation beam 110 and this can be referred to as an absolute wavelength reference (AWR). The calibration apparatus 350 uses a transition profile of a known energy transition to provide the AWR and/or ABR, as described below. The control system 185 can compare the AWR and/or ABR with the spectral property of the radiation beam 310 that is sensed by the metrology system 320 to determine whether the metrology system 320 needs to be calibrated or recalibrated (if previously calibrated).

In particular the measuring device 340 may be calibrated by using an AWR based on the atomic absorption transition of platinum atoms at 193.4369 nanometers (nm) in a platinum galvatron. Similarly, the bandwidth measurement by the BAM may be calibrated by using an ABR based on the same atomic absorption transition at 193.4369 nm of platinum atoms. For other implementations the atomic transition of Fe at 248.3271 nm may be used for the metrology calibration, for example, of a KrF laser. Other implementations may use other transitions.

As described more fully below, the calibration apparatus 350 supplies the AWR and/or ABR to the control system 185, and the control system 185 uses the AWR and/or ABR to determine whether the metrology system 320 is providing accurate values for the spectral property measurement. For example, the ABR is compared with the bandwidth of the metrology beam 310 as sensed by the measuring device 340, and if the sensed bandwidth does not match the ABR, then the control system 185 determines how much the sensed bandwidth deviates from the ABR to determine how to adjust a scale of the metrology system 320.

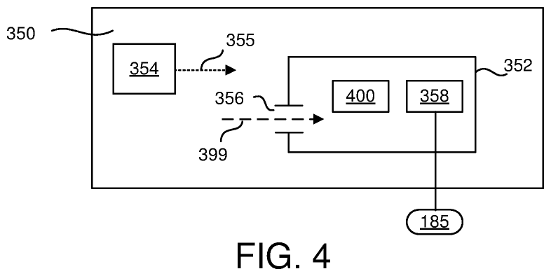

Referring to FIG. 4, the calibration apparatus 350 includes a calibration tool 352 and a calibration radiation source 354 that produces a calibration radiation beam 355. The calibration tool 352 includes an aperture 356 and at least one detector 358 that communicates with the control system 185. Moreover, the calibration apparatus 350 houses a material 400 having an optical transition profile with a known energy transition. A testing or radiation beam 399 (which can be either the calibration radiation beam 355 or the radiation beam 310 (FIG. 3)) interacts with the material 400 to produce a transition (for example, absorption) profile of the energy transition of the material 400, and this transition profile is detected by the detector 358.

The transition profile is indicative of a relationship between a characteristic associated with an interaction between the material 400 and the wavelength of the testing radiation beam 399. Thus, in order to detect the transition profile, the wavelength of the testing radiation beam 399 is measured as it is scanned across a wavelength interval, i.e., range, that includes the wavelength of the energy transition. Wavelength scanning involves the systematic variation of the wavelength of incident radiation through a range of wavelengths. Thus, in other words, the wavelength of the testing radiation is varied from a first endpoint wavelength in a range of wavelengths to a second endpoint wavelength in the range of wavelengths. The variation may be continuous, or stepped, or proceed in any other pattern that is suitable for a given application.

The calibration radiation source 354 can be a single frequency laser in which case the calibration radiation beam 355 is quasi-monochromatic radiation having a very small bandwidth and low phase noise. The calibration radiation source 354 is selected so that the wavelength of the calibration radiation beam 355 can be scanned, i.e., varied through a range that includes the known energy transition of the material 400, and this wavelength should be within the wavelength range of the radiation beam 110. Thus, if the material 400 has a known energy transition in the DUV portion of the spectrum, then the calibration radiation source 354 produces a calibration radiation beam 355 that has a wavelength that can be scanned across a range including that portion of the spectrum.

The material 400 can be made up of a vapor of atoms or molecules. The material 400 can be any material that has a known energy transition that occurs within the wavelength range of the radiation beam 110. Thus, as mentioned above, if the radiation beam 110 has a wavelength in the DUV range, then the material 400 is selected and the known energy transition is selected to be in that same DUV range. In some implementations, the material 400 is platinum that has a known transition at 193.4369 nm. In some implementations the material 400 is iron that has a known atomic transition at 248.3271 nm. Other materials may be used.

The interaction between the testing radiation beam 399 (which, again, can be the radiation beam 310 or the calibration radiation beam 355) and the material 400 causes a change in one or more characteristics of the testing radiation beam 399 and/or the material 400 when the wavelength of the testing radiation beam 399 overlaps the known energy transition wavelength. This change in the characteristic is detected by the detector 358 and from this changing characteristic, the spectral profile of the testing radiation beam 399 can be obtained.

The material 400 can be contained within a vapor cell or enclosure. In some implementations, as discussed below, the material 400 is produced as a discharge plasma and is a part of a laser galvatron, which is an opto-galvanic sensor including a hollow cathode lamp that takes advantage of the resonance phenomenon between the discharge plasma of the material 400 and the testing radiation beam 399.

The aperture 356 provides a path for receiving the testing radiation beam 399. The control system 185 analyzes the absorption profiles of the energy transition due to the interaction between the testing radiation beam 399 and the material 400 to determine whether the metrology system 320 needs to be calibrated, for example, by adjusting the scale at which the metrology system 320 measures the spectral property or property of the radiation beam 310. The calibration apparatus 350 may include components other than or in addition to those shown in FIG. 4.

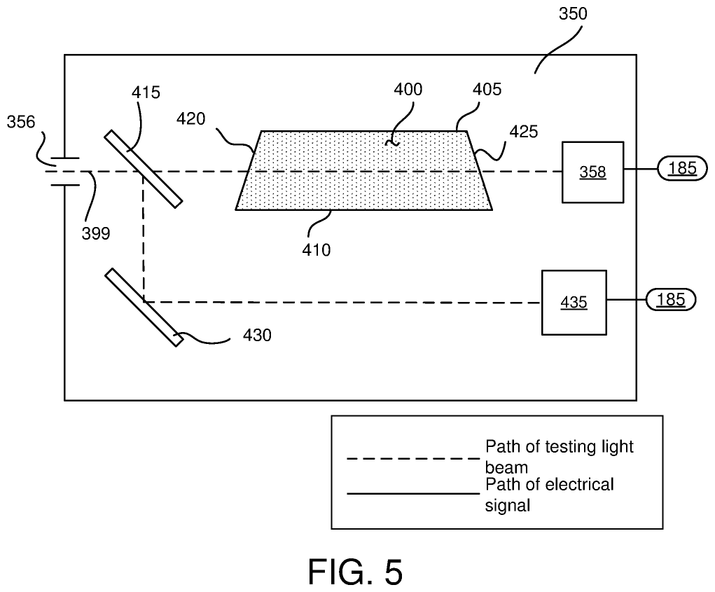

FIG. 5 shows an example of an arrangement for the calibration apparatus 350. In this calibration apparatus 350, the material 400 is housed in a cell 405. The cell 405 is defined by a wall 410 that is made of a rigid and chemically inert substance that retains the material 400. Moreover, the cell 405 includes at least an input window 420 and an output window 425 through which the testing radiation beam 399 can pass. The cell 405 is sealed from the external environment in order to contain the material 400.

The calibration apparatus 350 also includes the detector 358. The detector 358 is set up to detect the characteristic associated with the interaction between the material 400 and the testing radiation beam 399 as the testing radiation beam 399 is directed through the material 400 and while the wavelength of the testing radiation beam 399 is caused to vary across a range of wavelengths including the known energy transition.

The calibration apparatus 350 can also include a beam splitter 415 that redirects a portion of the testing radiation beam 399 toward a mirror 430 and a detector 435 to monitor the power of the testing radiation beam 399 to normalize the signal sensed by the detector 358.

In some implementations, the calibration apparatus 350 is configured as a field-service tool, which is a standalone component that includes a housing that holds the cell 405 and the detector 454 as well as an aperture 356 that permits the testing radiation beam 399 to pass. In other implementations, the calibration apparatus 350 is integrated into the metrology system 320. In some implementations, the calibration apparatus 350 is configured to automatically calibrate the metrology system 320 on a periodic basis or when some event occurs that indicates that calibration may be necessary or desirable. In this preferred such an embodiment, the scanning and calibration sequence is automated and programmed into the control electronics for the laser.

As mentioned, in some embodiments the wavelength range of the scan is chosen so as to include an absorption wavelength of the platinum vapor cell. For example, the strong absorption at 193.4369 nm is used, and the laser may be programmed to scan, e.g., progressively increase, through a range of wavelengths from a wavelength of about 193.434 nm to a wavelength of about 193.440 nm. When the laser wavelength coincides with the absorption wavelength, a substantial reduction in signal (10-50%) is seen by the detector 358.

One issue that arises in the measurement of one or more of the spectral properties of the radiation beam 110 is broadening of the spectral line of the transition in the vapor cell due to Doppler broadening. Doppler broadening is a phenomenon in which spectral lines are broadened due to the motion of the atoms or molecules in the vapor cell that emit or absorb the light. The Doppler effect causes the light to be shifted in frequency in the reference frame of the moving atom, or, equivalently, in the lab reference frame, the transition wavelength of the moving atom is shifted, depending on the velocity of the emitter or absorber. This shift is proportional to the velocity of the emitter or absorber, and to the wavelength of the light. This distribution of velocities in a vapor (thermal in origin) has the effect of broadening the measured linewidth.

Specifically, the intrinsic or natural linewidth of the atomic transition of platinum at 193.4369 nm is very narrow, estimated as being on the order of a few femtometers (fin). However, the linewidth of the atomic absorption transition in the platinum galvatron lamp is broadened by the Doppler effect as explained above. Depending on the temperature of the discharge plasma in the galvatron lamp, the linewidth of the platinum transition at 193.4369 nm in the galvatron could be broadened by a factor of several hundred times, as broad as about 500 fm for a galvatron lamp discharge plasma having a temperature of about 2000 K. The Doppler line broadening compromises the accuracy of the wavelength and bandwidth calibrations by the AWR and the ABR using the atomic transition at 193.4369 nm in the platinum galvatron.

In order to reduce the potential for decreased accuracy due to Doppler broadening, according to an aspect of an embodiment, saturated absorption spectroscopy, also referred to as Doppler-free spectroscopy or Doppler-free SAS, is used to avoid the Doppler line broadening of measurement of the atomic transition of the material in the vapor cell and so to improve the accuracy of wavelength and/or bandwidth measurements using AWR and ABR, respectively, for DUV lasers.

Saturated absorption spectroscopy or SAS uses a pump-probe arrangement. A laser beam known as the pump beam and having a relatively high intensity is sent through the vapor in the vapor cell. A counter-propagating weak beam known as a probe beam is also sent through the vapor at the same frequency and along the same path through the vapor but in a direction opposed to the direction of the pump beam. The absorption of the probe beam is detected by a detector for various frequencies of the beams. Under these circumstances the stronger beam, the pump beam, reduces the absorption experienced by the weaker probe beam over a very narrow range of frequencies that can approach the natural width determined by the transition. In some arrangements a second probe beam is sent through the vapor in the same direction as the first probe beam but along a different path unaffected by the pump beam. The signals produced by the two probe beams at their respective detectors are subtracted from each other and the difference between the two signals is recorded.

In other words, if the calibration radiation is approximately on resonance, the pump beam and the probe beam address the same atoms, those with velocity vectors nearly perpendicular to the direction of beam propagation. Although this description refers to atoms, one of ordinary skill in the art will appreciate that the description also applies to molecules. In the two-state approximation of an atomic transition, the strong pump beam will cause many of the atoms to be in the excited state. When the number of atoms in the ground state and the number of atoms in the excited state are approximately the same, the transition is said to be saturated. Thus, as used herein, the term “saturate” means to cause the number of species (atoms, molecules) in the ground state and a number of species in an excited state to be approximately the same. When a photon from the probe beam passes through the vapor there is a high probability that, if it encounters an atom (or molecule), the atom will be in the excited state and will thus undergo stimulated emission, with the photon passing through the sample. Thus, as the calibration radiation frequency is swept across the resonance, a small dip in the absorption feature will be observed at each atomic transition (generally hyperfine resonances). The stronger the pump beam, the wider and deeper the dips in the Gaussian Doppler-broadened absorption feature become. Under ideal conditions, the width of the dip can approach the natural linewidth of the transition.

Thus, in Doppler-free spectroscopy the strong laser beam is used to saturate the absorption of a weaker probe beam. The saturation occurs only when the strong and weak beams are both interacting with the same velocity population in the material, i.e. when the laser wavelength is at the center of the transition. Hence, the dip feature is not subject to Doppler broadening. As a result, there is no Doppler broadening of the absorption line, and the line is very narrow. When the strong and weak beams are not interacting with the same velocity population, the absorption of the weak beam is the same as that of the other probe beam. Thus the differential signal between the two probes is non-zero only when the first probe beam is interacting with the strong beam, and the resultant signal is a Doppler-free transition profile.

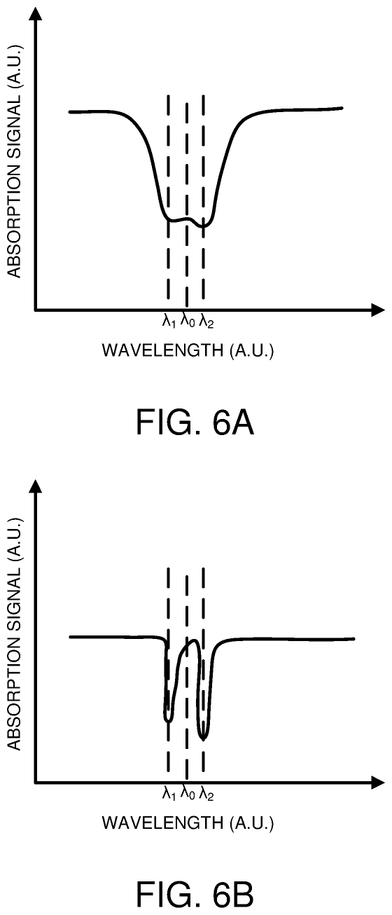

FIGS. 6A and 6B are non-quantitative graphical representations of expected transition profiles related to measurements of the output of a DUV laser. The trace in FIG. 6A is a representation of a transition profile around the platinum absorption transition line at 193.4369 nm (o) obtained using standard (i.e., not Doppler-free) spectroscopy while scanning the wavelength of supplied DUV laser radiation through the wavelength range including the transition. Thus, the Doppler line broadening is not removed. There are actually two apparent transitions, one at λ₁ and one at λ₂, separated by about 200 fm around 193.4369 nm. These two transitions are only barely resolved in the trace in FIG. 6A because they are convoluted with the DUV laser spectral profile. The trace in FIG. 6B is a representation of a transition profile obtained using Doppler-free spectroscopy while scanning the wavelength of the DUV laser radiation through the wavelength range including the transition. The transitions at λ₁ and λ₂ are much more clearly resolved in the trace in FIG. 6B. As described in more detail below, however, there is additional structure in the traces due to the fact that platinum has multiple naturally occurring isotopes that have absorption transition lines that are slightly different from one another.

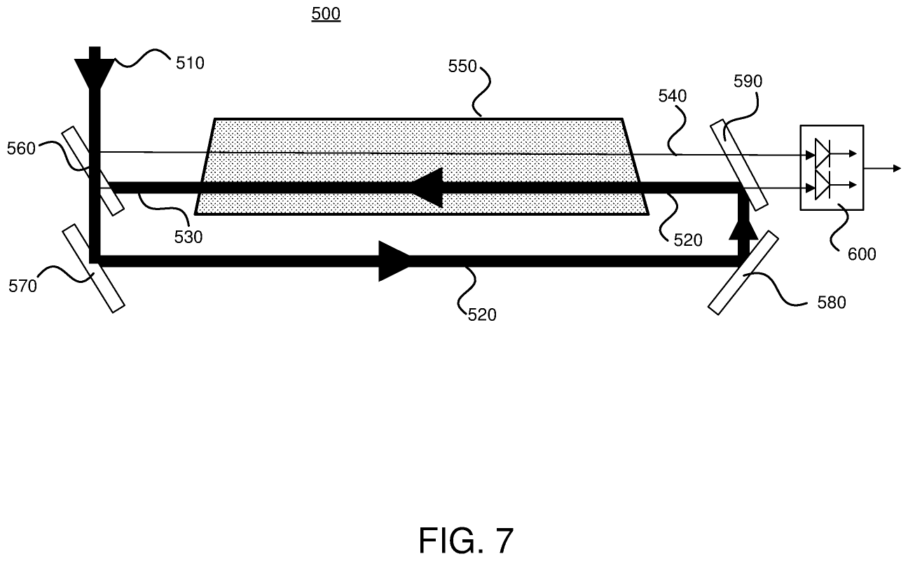

FIG. 7 is a schematic diagram of a calibration module 500 for laser beam absorption line measurement metrology according to an aspect of an embodiment. As shown, an incident laser beam 510, which may originate from a dedicated laser source or be derived from the operational laser beam of the photolithographic device, is divided into three beams by a beam splitter 560 having front and rear partially reflecting surfaces. The three beams include a pump beam 520, a first probe or absorption beam 530, and a second probe or absorption beam 540. The pump beam 520 is the most intense beam. It is directed along a first path through a vapor cell 550 by an optical arrangement including a mirror 570, a mirror 580, and a beam splitter 590. The other two beams, first absorption beam 530 and second absorption beam 540, are of lower intensity than the pump beam 520. They are sent through the vapor cell 550 in a direction opposite that of the pump beam 520 by the beam splitter 560.

The first absorption beam 530, i.e., the probe beam that is arranged to overlap the counterpropagating pump beam 520 inside the cell 550 is sometimes referred to as the “overlap” beam. The second absorption beam 540, the other probe beam, which does not overlap with the pump beam 520, is sometimes called the “reference beam.” In this arrangement, second absorption beam 540 has the normal Doppler line broadening while first absorption beam 530 has a Doppler-free hole at the center of the Doppler broadened absorption line. The differential detection of the intensity of two absorption or probe beams by differential detector 600 recovers the Doppler-free absorption line with the Doppler line broadening removed.

The first and second absorption beams 530 and 540 are laterally (with respect to beam direction) displaced from each other, i.e., laterally separated in space, and are directed in a propagation direction to pass through the absorption cell 550 containing atomic or molecular vapor for atomic/molecular absorption transition measurement. The first and second absorption beams 530 and 540 carry a relatively smaller portion of the incident beam intensity with the majority of the incident beam intensity being carried by the pump beam 520.

The pump beam 520 is directed to traverse the absorption cell 550 in the direction opposite to the propagation direction of the first and second absorption beams 530 and 540 and along a path that spatially overlaps the propagation path of the first absorption beam 530.

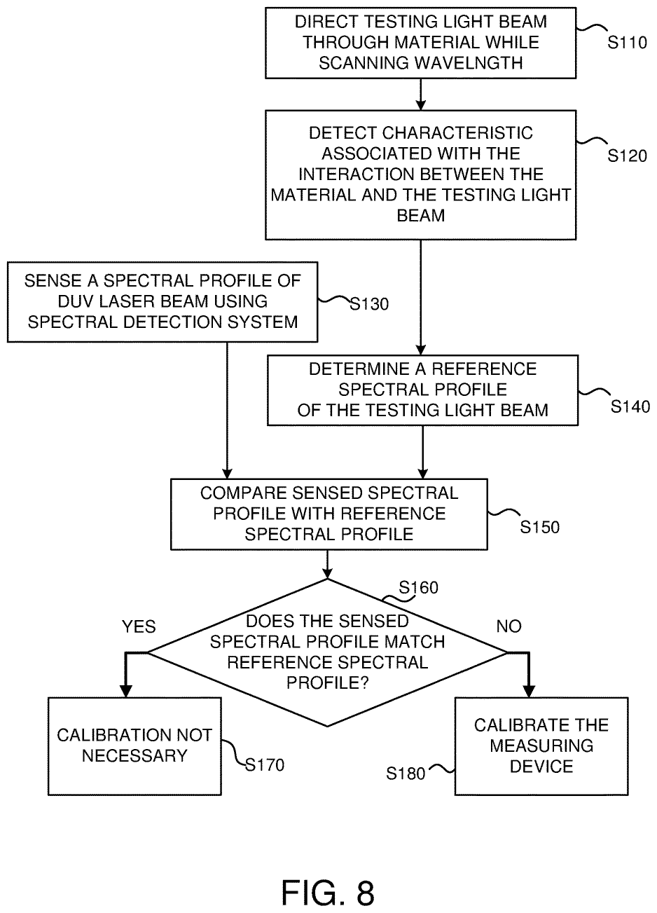

FIG. 8 is a flow chart describing a procedure performed by the photolithography system 100 to determine whether to calibrate the metrology system 320 and to calibrate the metrology system 320 if necessary.

Initially, in a step S110, a testing light beam is directed through the material 400 as described above. The testing light beam can be the calibration light beam 355 or the light beam 310. In a step S120 one or more characteristics associated with the interaction between the material 400 and the testing light beam are detected while the testing light beam is directed to pass through the material and while the wavelength of the testing light beam is scanned across a known energy transition of the material. As the wavelength of the testing light beam is varied, so are the wavelengths of the probe beams 530, 540 since the probe beams are derived from the testing light beam. For example, the detector 358 of the calibration tool 352 (both shown in FIG. 4) detects this characteristic.

Meanwhile, in a step S130, the spectral profile of the light beam 310 is sensed, for example, by the measuring device 340.

In a step S140 a reference spectral profile of the testing light beam is determined as explained in more detail below. Then in a step S150 the sensed spectral profile of the light beam 310 output from the measuring device 340 is compared with the reference spectral profile determined in step S140. The control system 185 can perform this comparison. For example, the control system 185 can compare two or more data values or points of the reference spectral profile with two or more data values or points of the sensed spectral profile to determine if these data values match. In one example, the control system 185 compares a width W(ref) of the reference spectral profile with a width W(sensed) of the sensed spectral profile to determine whether the width of the sensed spectral profile matches that of the reference spectral profile.

In a step S160 it is determined whether the sensed spectral profile matches within acceptable tolerances the reference spectral profile. If it is determined that the sensed spectral profile matches the reference spectral profile then it is determined in a step S170 that it is not necessary to calibrate the measuring device, e.g., measuring device 340. If, however, it is determined in step S160 that the sensed spectral profile does not match the reference spectral profile then in a step S180 the measuring device is calibrated.

In one embodiment, the measuring device is calibrated by adjusting the scale of the measuring device. For example, the control system 185 can send a signal to the metrology system 320 to adjust the scale. As another example, it is possible for the control system 185 to instead output a signal that indicates how the scale of the measuring device 340 should be adjusted and, based on that signal, an operator of the photolithography system 100 can make the adjustment to the measuring device 340. The adjustment to the metrology system 320 can be performed in any suitable manner. For example, the adjustment can be to simply add an offset to the sensed spectral profile of the light beam 310 that is sensed by the metrology system 320 whenever there is a mismatch between the sensed spectral profile of the light beam 310 and the reference spectral profile.

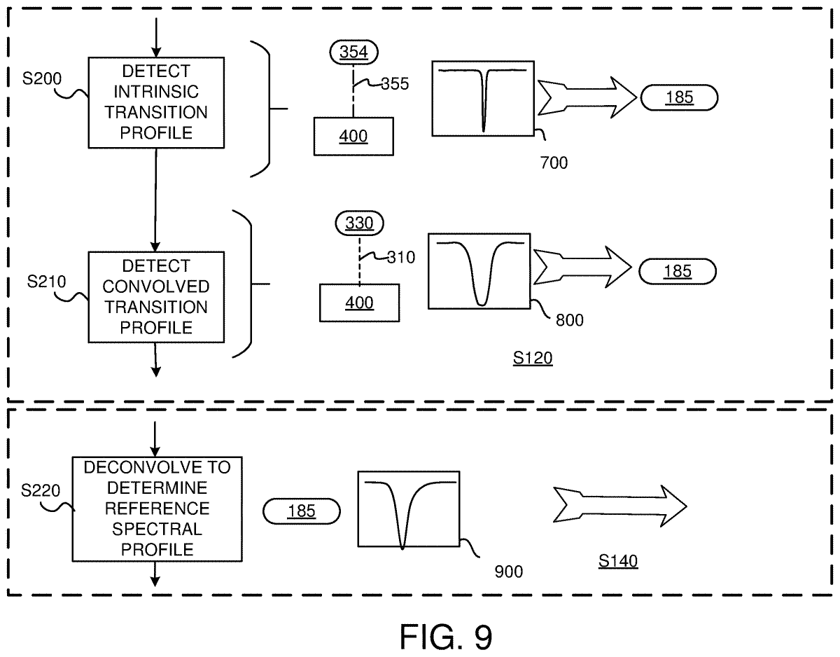

FIG. 9 is a diagram showing additional details about the performance of certain steps appearing in the flow chart in FIG. 8. For example, step S120 in FIG. 8 is detecting a characteristic associated with the interaction between the material and the testing light beam and step S140 is determining a reference spectral profile of the testing light beam. In order to perform this step, first, in a step S200 an intrinsic transition profile 700 of a known energy transition of the material 400 is detected. The intrinsic transition profile 700 can be detected by detecting a characteristic associated with the interaction between the material 400 and the calibration light beam 355 while the calibration light beam 355 passes through the calibration material 400 as the wavelength of the calibration light beam 355 is scanned across the known energy transition of the calibration material 400. The intrinsic transition profile 700 is similar to an instrument function or transfer function of the material 400. The calibration light beam 355 is scanned across the wavelengths that are known to be associated with the known energy transition of the material 400 so that the entire energy transition is recorded in the intrinsic transition profile 700.

Moreover, the calibration light beam 355 can be scanned across the wavelengths using any suitable scanning technique. The calibration light source 354 may be a single frequency laser and tuned in wavelength by one of several methods. The first exemplary method is to change the temperature of the materials used to generate the calibration light beam 355. For example, the temperature of the gain medium (which can be crystals) used to produce single frequency DUV light at 193.4 nm can be adjusted. The second exemplary method is to adjust the current of a seed diode laser within the calibration light source 354 if the calibration light source 354 includes a seed diode laser. The third exemplary method is to adjust the incidence angle of a grating if the cavity of the seed light source within the calibration light source 354 includes a grating.

As described above, the calibration apparatus 350 may include a galvatron in which case the material 400 is a gas or discharge plasma produced from an electrode that is made of the material and placed within the vapor cell 550.

Because the calibration light beam 355 has a much narrower bandwidth than the bandwidth of the light beam 310, the intrinsic transition profile 700 provides an instrument response function associated with the material 400.

Next, a convolved transition profile 800 in which the intrinsic transition profile 700 is altered by a spectral shape of the light beam 310 is detected in a step S210. The convolved transition profile 800 includes the intrinsic transition profile 700 as broadened by the spectral bandwidth of the light beam 310. The convolved transition profile 800 can be detected by detecting a characteristic associated with the interaction between the material 400 and the light beam 310 while the light beam 310 is directed through the material 400 and while the wavelength of the light beam 310 is scanned, e.g., progressively varied, through a range including the wavelength at which the known energy transition of the material 400 occurs. Specifically the light beam 310 is scanned across the wavelengths that are known to be associated with the known energy transition so that the entire energy transition is recorded in the convolved transition profile 800. Moreover, the light beam 310 can be scanned across the wavelengths using any suitable scanning technique.

Step S140 of the process described in FIG. 8 is determining a reference spectral profile of the testing light beam. In FIG. 9 this step of determining the reference spectral profile 900 is carried out by deconvolving the intrinsic transition profile 700 from the spectral shape of the light beam 310 within the detected convolved transition profile 800 in a step S220. The resulting reference spectral profile 900 thus exhibits reduced effects of broadening of the spectral profile of the light beam 310.

In some implementations, the deconvolution is performed by computing the Fourier transform (C) of the convolved transition profile 800, computing the Fourier transform (I) of the intrinsic transition profile 700, and applying a deconvolution in the frequency domain to solve for R, which is the Fourier transform of the reference spectral profile 900. The reference spectral profile 900 is the inverse Fourier transform of R.

The intrinsic transition profile 900 can be stored within memory for future measurements. Thus, for example, there may be a temporal gap between performing the step S200 of detecting the intrinsic transition profile 700 and the step S210 of detecting the convolved transition 800. And, during this time, the intrinsic transition profile 700 can be stored within memory and accessed when needed for performing a future deconvolution.

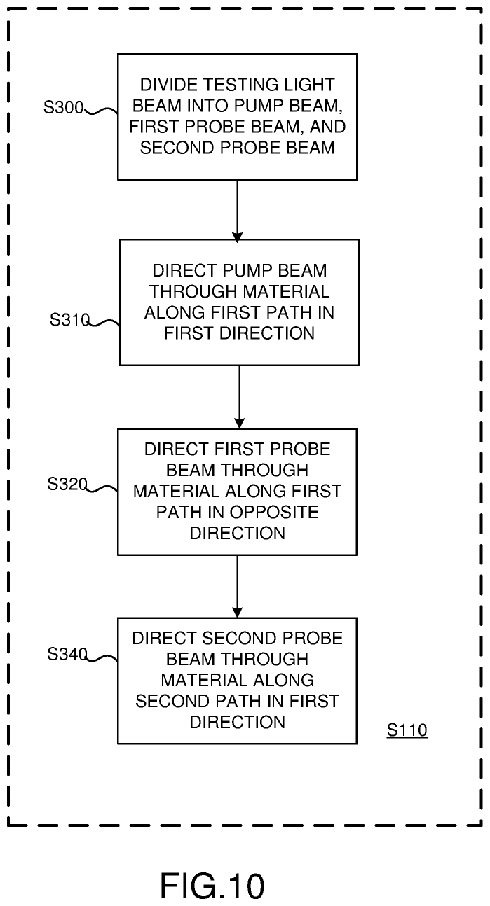

FIG. 10 is a flow chart showing details of a procedure for performing the step S110, directing the testing light beam through the calibration material, of FIG. 8, according to an aspect of an embodiment. As described above, according to an aspect of an embodiment, the testing light beam, which may be either the beam 355 or 310 depending on which transition profile is desired, is caused to pass through the calibration material in such a way that the effects of Doppler shifting are substantially negated. Thus, in a step S300 the testing light beam is divided into a pump beam, a first probe beam, and a second probe beam. Then, in a step S310, the pump beam is directed through the calibration material having a known transition along a first path in a first direction. At the same time, in a step S320, the first probe beam is directed through the material along the first path in a direction opposite to the first direction. Also at the same time, in a step S340, a second probe beam is directed through the material along a second path in the first direction, that is, in the same direction as the first probe beam. While this is occurring the wavelength of the testing light beam is scanned through the known transition to obtain the desired transition profile.

The foregoing describes using deconvolution to recover the laser bandwidth. One of ordinary skill in the art will appreciate that this is just one example of a system and method for determining the laser bandwidth using saturated absorption spectroscopy and that other systems and methods could be used instead. For example the measurement obtained using saturated absorption spectroscopy could be correlated with bandwidth as measured using another reference standard such as a grating spectrometer or high precision bandwidth analysis module.

Typically, a material for the vapor cell 550 is chosen to provide a resonance wavelength in a vicinity of an intended operational wavelength of the laser. These considerations make platinum a good candidate material in a vapor cell to be used with an ArF laser and iron a good candidate material in a vapor cell to be used with a KrF laser. Other candidate materials include carbon, aluminum, and arsenic.

Candidate materials can be found, for example, by identifying absorption transition wavelengths within the tuning range of the laser (e.g., in a range of about 192.9 nm to about 193.9 nm for ArF lasers and in a range of about 247.9 nm to about 248.9 nm for KrF lasers) from the neutral (i.e., nonionized) atoms. In some implementations it will be desirable to scan wavelengths in a range of 4 to 5 times the laser bandwidth around the laser center wavelength.

According to another aspect of an embodiment, another technique for obtaining a narrower linewidth of the atomic absorption transition in the vapor cell involves using an isotopically separated or naturally monoisotopic elemental material in the vapor cell.

For example, platinum has four naturally occurring isotopes with any appreciable concentration (platinum-194 at 32.86%, platinum-195 at 33.78%, platinum-196 at 25.21%, and platinum-198 at 7.36%). These isotopes have transition wavelengths that differ from one another. When all four isotopes are present in the galvatron cathode in these naturally occurring concentrations the output of the spectral analysis system yields four distinct peaks that are not well-resolved. This makes analysis of the peak widths much less certain, especially if one is trying to determine full width percentage spreads (FWXX widths) where XX is less than 50%.

Using isotopically separated platinum, that is, platinum in which one of the isotopes has been concentrated, results in an absorption linewidth dominated by a single atomic transition of the concentrated isotope which results in a narrower absorption linewidth.

The selected isotope may be concentrated, for example, so that it makes up at least 90% of the platinum by weight. A lower concentration leaves open the possibility that transitions from other isotopes will adversely affect measurement of the transition linewidth.

Concentration methods may be used to concentrate a single isotope in cathode materials having more than one abundant naturally occurring isotope. For example, isotopically concentrated platinum can be produced using any suitable form of isotopic separation, for example, electromagnetic separation.

There are also materials in which the abundance of one isotope is naturally predominant, e.g., greater than 90%. For example, there are 19 monoisotopic elements having only one naturally occurring isotope that determines their invariant standard atomic weight and would not require concentration. These are beryllium: Be-9, fluorine: F-19, sodium: Na-23, aluminum: Al-27, phosphorus: P-31, scandium: Sc-45, manganese: Mn-55, cobalt: Co-59; arsenic: As-75, yttrium: Y-89, niobium: Nb-93, rhodium: Rh-103, indium: In-113, iodine: I-127, cesium: Cs-133, lanthanum: La-139, praseodymium: Pr141, europium: Eu-153, terbium Tb-159, and gold: Au-197.

In some implementations it will be beneficial not only that the candidate material have an absorption transition in the proper range but also exhibit a relatively high transition strength. In some implementations it will also be beneficial for the candidate material to have a lower level energy near ground state to ensure a larger population on this level. Similarly, in some implementations it will also be beneficial for the candidate material to have a first excited state (other than the sate transitioned to by the laser) that is high in energy so that the population is predominantly in the lower energy level of the neutral atom, not thermally distributed in a bunch of higher levels that will not absorb laser radiation at the proper wavelengths.

In addition, in some implementations it will also be beneficial for the candidate material to be easy to sputter or vaporize with a resulting high vapor pressure so the galvatron vapor cell is able to render a greater amount of this material into its vapor phase.

In some implementations it will also be beneficial for the candidate material to have a high ionization energy so that more of its atoms remain as neutrals rather than being ionized.

In addition to the potential advantages of using a monoisotopic material, there are also potential advantages to using a monoisotopic material having a relatively high mass. Monoisotopic material having a higher mass can be expected to provide a better signal for the saturated absorption technique. In general, the higher the atomic mass, the more likely there are to be multiple stable isotopes (e.g., cadmium) because the material can absorb multiple neutrons without becoming radioactive.

If, however, a material is not naturally monoisotopic or at least does not have a single naturally predominant isotopic fraction, then isotopic separation is typically easier for the lower atomic mass and the different isotope lines can be far enough apart that they do not interfere with each other, although signal strength can be expected to be lower. Thus the selection of an optimal atomic mass may in some implementations represent a tradeoff.

As a specific nonlimiting example, carbon-12 (¹²C or 12C) satisfies many of these criteria, although its relatively low atomic mass indicates that its absorption can be expected to be relatively weaker. Aluminum is another good candidate material. The following table lists some additional candidate materials with their corresponding absorption transition wavelengths.

| Element | Wavelength (nm) |
|---|---|
| C-12 | 193.09054 |
| Al | 193.2268 |
| Al | 193.6457 |
| As | 193.759 |
| Be | 192.967 |
| Fe | 193.0701 |
| Fe | 193.3757 |
| Fe | 193.4535 |
| Fe | 193.72683 |
| Ge | 192.9828 |
| Ge | 193.404833 |
| Ge | 193.748238 |
| Ge | 193.8301 |
| Pt | 192.9255 |
| Pt | 193.2031 |
| Pt | 193.224406 |
| Pt | 193.436846 |
| Pt | 193.742404 |
| Sc | 192.95717 |
| Sc | 193.0994 |
| Sc | 193.20909 |
| Sc | 193.41488 |
| Sc | 193.58599 |
| Sc | 193.58314 |
| Sc | 193.57528 |
| Sc | 193.62351 |
| Sc | 193.64116 |
| Sc | 193.72925 |
| Sc | 193.76 |
| Sc | 193.83962 |
| Sc | 193.84924 |
| Sc | 193.8666 |
| Sn | 192.905 |
| Sn | 193.31486 |

These examples relate to materials for ArF lasers operating at about 193 nm. It will be apparent to one of ordinary skill in the art that the same analysis can be carried out to identify suitable candidate materials for KrF lasers operating at about 248 nm.

Thus, the linewidth narrowing achieved by using Doppler-free saturated absorption spectroscopy can be even further enhanced by using a material in the vapor cell that is naturally monoisotopic or at least has a single naturally predominant isotopic fraction or has been isotopically concentrated (natural isotopic abundance altered so that one of the isotopes has an abundance greater than occurs in nature) to have a predominant isotopic fraction.

This potential benefit is not, however, limited to Doppler-free saturated absorption spectroscopy. The use of isotopically concentrated material can also yield narrower linewidth measurements in arrangements which perform saturated absorption spectroscopy without Doppler correction such as those described above in connection with FIG. 5.

As mentioned, the cell 405 (FIG. 5) or vapor cell 550 (FIG. 7) may be realized as a see-through hollow cathode lamp referred to as a galvatron. The galvatron is filled with a filler gas such as hydrogen, helium, neon, or mixtures of argon and neon, krypton and neon, or xenon and neon. An anode and a cathode are mounted within the lamp with the cathode having an annular or tubular shape. In some embodiments the cathode and cell are oriented in a T-shape, with the cathode bored completely through to allow the propagation of a beam through the cathode. The cathode is fabricated from or at least has a coating in its internal (beam facing) surface made of any of a large number of elemental materials, i.e., an element appearing on the periodic table of elements such as silver, aluminum, gold, iron, zirconium, platinum, arsenic, and carbon. In some embodiments the elemental material may be one of the monoisotopic elements having only one naturally occurring isotope listed above.

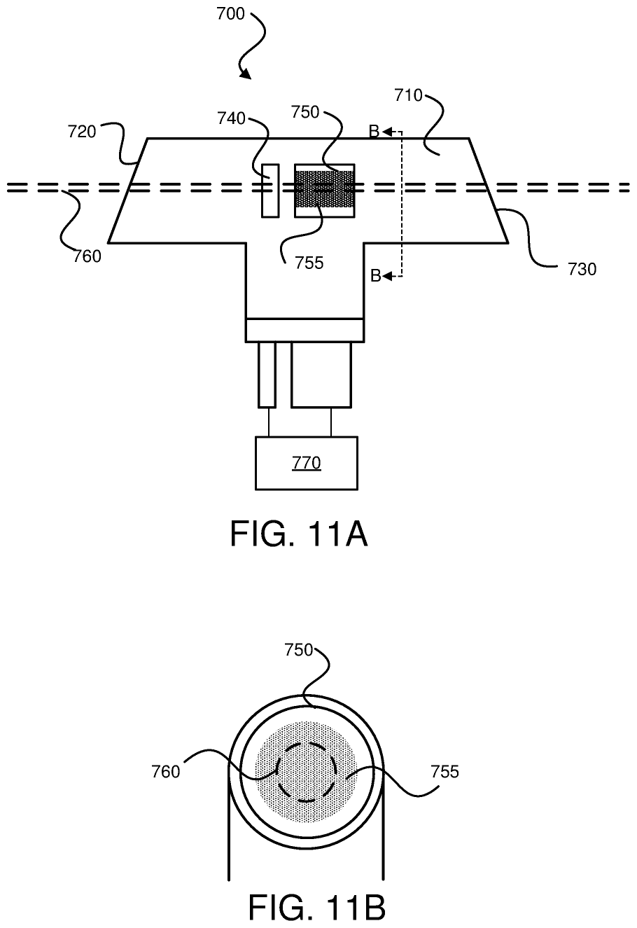

FIG. 11A shows an exemplary galvatron 700 which includes a transparent vacuum tube 710 having an entrance window 720 and an exit window 730. An anode 740 and a cathode 750 are mounted therein. A laser beam, identified by reference numeral 760, enters entrance window 720, passes through the interior of cathode 750, and exits through exit window 730. Current source 770 powers the galvatron 700. FIG. 11B shows the arrangement of the hollow cathode 750 and the vapor 755 within the volume of the hollow cathode 750 viewed from the direction of propagation of the beam 760.

In use, an electrical current is conducted through the anode 740 and cathode 750 causing a filler gas within the volume of the hollow cathode 750 to be ionized and to vaporize a portion of the cathode material to form a vapor 755. The ionized gas and the vaporous cathode material 755 form a plasma in the interior of the cathode 750 along the path of the laser beam 760. For certain wavelengths of the laser beam 760, and depending upon the composition of the filler gas and the cathode material, a resonance can occur between the plasma and the incident laser beam 760. When the wavelength of the laser is resonant with certain absorption wavelengths of atoms and molecules within the plasma, electrical properties of the plasma are altered.

The resonance within the plasma affects electrical properties of the current conducted through the anode 740 and cathode 750. These electrical properties are detected and correlated with those of the laser beam 760 to yield a determination of the wavelength of the laser beam 760. Typically, the wavelength of the laser beam 760 is adjusted to achieve a maximum resonance, with the correct wavelength, corresponding to the maximum resonance, being predetermined from the composition of the filler gas and cathode materials. 760. These and other details concerning galvatrons for the uses described herein can be obtained from U.S. Pat. No. 5,450,207, issued Sep. 12, 1995, and titled “Method and Apparatus for Calibrating a Laser Wavelength Control Mechanism.

Typically, a specific cathode material is chosen to provide a resonance wavelength in a vicinity of an intended operational wavelength of the laser. These considerations make platinum a good candidate material in a galvatron lamp to be used as a vapor cell with an ArF laser and iron a good candidate material in a galvatron lamp to be used as a vapor cell with a KrF laser. Other candidate materials include carbon and arsenic. Essentially, however, the various selection criteria referenced above for the vapor cell of the Doppler-free SAS embodiments will also serve as selection criteria for the cathode material for the galvatron of FIGS. 11A and 11B.

Some of the above description is in terms of functional block diagrams with some functions allocated to some blocks and other functions allocated to other blocks. It will be understood that the division between blocks and the allocations are arbitrary and that different divisions and allocations are possible so long as the overall functions are carried out as described above.

The above description includes examples of multiple embodiments. It is, of course, not possible to describe every conceivable combination of components or methodologies for each of these embodiments, but one of ordinary skill in the art may recognize that many further combinations and permutations of elements of the various embodiments are possible based on the disclosure. Accordingly, the described embodiments are intended to be representative of and encompass all such alterations, modifications, and variations that fall within the spirit and scope of the appended claims.

Furthermore, to the extent that the term “includes” is used in either the detailed description or the claims, such term is intended to be inclusive in a manner similar to the term “comprising” as “comprising” is construed when employed as a transitional word in a claim. Also, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described m the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added.

Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

The embodiments can be further described using the following clauses:

1. A metrology system for measuring a spectral property of a beam of excimer laser radiation, the metrology system comprising:
a beam separator for separating a beam of metrology radiation from the beam of excimer laser radiation;
a source of a beam of calibration radiation;
a measuring module arranged to receive the beam of metrology radiation and configured to measure a spectral property of the beam of metrology radiation and generate a measurement signal indicative of the spectral property;
a calibration module arranged to receive either the beam of metrology radiation or the beam of calibration radiation as an input beam of radiation, the calibration module including
a material having a known energy transition at a specified wavelength,
an optical arrangement configured to
divide the beam of input radiation into a pump beam and first and second probe beams,
direct the pump beam through the material along a first path in a first direction, and
direct the first probe beam through the material along the first path in a second direction the opposite of the first direction and the second probe beam through the material along a second path in the second direction, and
a detector configured to
receive the first probe beam after the first probe beam has traversed the first path,
receive the second probe beam after the second probe beam has traversed the second path,
measure a property of the first probe beam and a property of the second probe beam as a wavelength of the beam of input radiation is caused to vary through a range of wavelengths including the specified wavelength,
obtain a difference between the property of the first probe beam and the property of the second probe beam, and
generate a first differential signal based on the difference between the property of the first probe beam and the property of the second probe beam when the input beam comprises the beam of metrology radiation and a second differential signal based on the difference between the property of the first probe beam and the property of the second probe beam when the input beam comprises the beam of calibration radiation; and
a control system arranged to receive the first differential signal and the second differential signal and adapted to generate an absolute reference signal based on the first differential signal and the second differential signal.

2. The metrology system of clause 1 wherein the control system is adapted to calibrate the measurement of the spectral property based on the absolute reference signal.

3. The metrology system of clause 1 wherein the pump beam saturates the material along the first path.

4. The metrology system of clause 1 further comprising a source for the beam of calibration radiation.

5. The metrology system of clause 1 wherein the spectral property is a center wavelength of the beam of metrology radiation.

6. The metrology system of clause 1 wherein the spectral property is a bandwidth of the beam of metrology radiation.

7. The metrology system of clause 1 wherein the material is platinum vapor.

8. The metrology system of clause 1 wherein the known energy transition is the atomic absorption transition of platinum atoms at 193.4369 nanometers.

9. The metrology system of clause 1 wherein the known energy transition is the atomic absorption transition of iron atoms at 248.3271 nanometers.

10. The metrology system of clause 1 wherein the optical arrangement comprises
a first beam splitter arranged to divide the first probe beam and second probe beam from the beam of input radiation and to direct the first probe beam along the first path and the second probe beam along the second path and
a plurality of mirrors arranged to direct a remaining portion of the beam of input radiation after the first probe beam and second probe beam have been divided out along the first path in the first direction.

11. A system for measuring a spectrum of an incident beam from a laser source, the spectrum exhibiting
a first amount of Doppler broadening, the system comprising:
an absorption cell containing an absorptive medium;
a first beam splitter having two reflective surfaces that generate a first beam and a second beam from the incident beam, the first beam and the second beam passing through the absorptive medium after reflection;
a second beam splitter positioned and oriented to generate a third beam from the incident beam, the third beam being directed to propagate in a direction opposite to and colinear with a direction of propagation of the second beam; and
a differential detector configured to receive the first beam and the second beam and generate a differential transition profile of the incident beam as a wavelength of the incident beam is varied through a range of wavelength values, the differential transition profile having a second amount of Doppler broadening, the second amount of Doppler broadening being less than the first amount of Doppler broadening,
wherein the absorptive medium comprises a material having one or more transition lines in the range of wavelength values.

12. The system of clause 11 wherein the absorptive medium comprises platinum vapor.

13. A metrology method comprising:
receiving a beam of input radiation,
dividing the beam of input radiation into a pump beam and first and second probe beams;
directing the pump beam through a material having a known energy transition at a specified wavelength along a first path in a first direction to saturate the material along the first path;
directing the first probe beam through the material along the first path in a second direction opposite the first direction;
directing the second probe beam through the material along a second path in the second direction; receiving the first probe beam after the first probe beam has traversed the first path;
receiving the second probe beam after the second probe beam has traversed the second path;
measuring a spectral property of the first probe beam and a spectral property of the second probe beam as a wavelength of the beam of input radiation is varied though a range of wavelengths including the specified wavelength;
measuring a difference between the property of the first probe beam and the property of the second probe beam;
generating a transition profile based on a difference between the spectral property of the first probe beam and the spectral property of the second probe beam;
generating an absolute reference based at least in part on the transition profile; and
calibrating a measurement of a spectral property of an excimer laser beam based at least in part on the absolute reference signal.

14. The metrology method of clause 13 wherein
the input radiation comprises either metrology radiation separated from an excimer laser beam or calibration radiation from a calibration radiation source,
the transition profile is a convolved transition profile when the input radiation comprises the metrology radiation or an intrinsic transition profile when the input radiation comprises the calibration radiation, and
generating an absolute reference based at least in part on the transition profile comprises generating an absolute reference based at least in part on the convolved transition profile and the intrinsic transition profile.

15. The metrology method of clause 13 further comprising generating the input radiation using a single wavelength laser source.

16. The metrology method of clause 13 wherein the spectral property is a center wavelength of laser radiation.

17. The metrology method of clause 13 wherein the spectral property is a bandwidth of laser radiation.

18. The metrology method of clause 13 wherein the material is platinum vapor.

19. The metrology method of clause 18 wherein the known energy transition is the atomic absorption transition of platinum atoms at 193.4369 nanometers.

20. The metrology method of clause 13 wherein the material is iron vapor.

21. The metrology method of clause 20 wherein the known energy transition is the atomic absorption transition of iron atoms at 248.3271 nanometers.

22. A metrology method comprising:
performing a measurement of a center wavelength of a deep ultraviolet excimer laser beam;
generating an absolute wavelength reference using Doppler-free spectroscopy; and
using the absolute wavelength reference to calibrate the measurement.

23. A metrology method comprising:
performing a measurement of a bandwidth of a deep ultraviolet excimer laser beam;
generating an absolute bandwidth reference using Doppler-free spectroscopy; and using the absolute wavelength reference to calibrate the measurement.

24. A metrology system for measuring a spectral property of a beam of excimer laser radiation, the metrology system comprising:
a beam separator for separating a beam of metrology radiation from the beam of excimer laser radiation;
a source of a beam of calibration radiation;
a measuring module arranged to receive the beam of metrology radiation and configured to measure a spectral property of the beam of metrology radiation and generate a measurement signal indicative of the spectral property;
a calibration module arranged to receive either the beam of metrology radiation or the beam of calibration radiation as an input beam of radiation, the calibration module including
a vapor of an elemental material having a concentrated proportion of an isotope of the elemental material, the isotope having a known energy transition at a specified wavelength,
an optical arrangement configured to
divide the beam of input radiation into a pump beam and first and second probe beams,
direct the pump beam through the material along a first path in a first direction, and
direct the first probe beam through the material along the first path in a second direction the opposite of the first direction and the second probe beam through the material along a second path in the second direction, and
a detector configured to
receive the first probe beam after the first probe beam has traversed the first path,
receive the second probe beam after the second probe beam has traversed the second path,
measure a property of the first probe beam and a property of the second probe beam as a wavelength of the beam of input radiation is caused to vary through a range of wavelengths including the specified wavelength,
obtain a difference between the property of the first probe beam and the property of the second probe beam, and
generate a first differential signal based on the difference between the property of the first probe beam and the property of the second probe beam when the input beam comprises the beam of metrology radiation and a second differential signal based on the difference between the property of the first probe beam and the property of the second probe beam when the input beam comprises the beam of calibration radiation; and
a control system arranged to receive the first differential signal and the second differential signal and adapted to generate an absolute reference signal based on the first differential signal and the second differential signal.

25. The metrology system of clause 24 wherein the control system is adapted to calibrate the measurement of the spectral property based on the absolute reference signal.

26. The metrology system of clause 24 wherein the spectral property is a center wavelength of the beam of metrology radiation.

27. The metrology system of clause 24 wherein the spectral property is a bandwidth of the beam of metrology radiation.

28. The metrology system of clause 24 wherein the elemental material comprises platinum.

29. The metrology system of clause 24 wherein the elemental material comprises iron.

30. The metrology system of clause 24 wherein the elemental material comprises carbon.

31. The metrology system of clause 24 wherein the elemental material comprises arsenic.

32. The metrology system of clause 24 wherein at least 90% of the elemental material comprises the isotope.

33. A system for measuring a spectrum of an incident beam from a laser source, the spectrum exhibiting a first amount of Doppler broadening, the system comprising:
an absorption cell containing an absorptive medium;
a first beam splitter configured to generate a first beam and a second beam from the incident beam, the first beam and the second beam passing through the absorptive medium after reflection;
a second beam splitter positioned and oriented to generate a third beam from the incident beam, the third beam being directed to propagate in a direction opposite to and colinear with a direction of propagation of the second beam; and
a differential detector configured to receive the first beam and the second beam and generate a differential transition profile of the incident beam as a wavelength of the incident beam is varied through a range of wavelength values, the differential transition profile having a second amount of Doppler broadening, the second amount of Doppler broadening being less than the first amount of Doppler broadening,
wherein the absorptive medium comprises a vapor of an elemental material having a concentrated proportion of an isotope of the elemental material, the isotope having a known energy transition at a specified wavelength.

34. The system of clause 33 wherein the elemental material comprises platinum.

35. The system of clause 33 wherein the elemental material comprises iron.

36. The system of clause 33 wherein the elemental material comprises carbon.

37. The system of clause 33 wherein the elemental material comprises arsenic.

38. The system of clause 33 wherein at least 90% of the elemental material comprises the isotope.

39. A metrology method comprising:
receiving a beam of input radiation;
dividing the beam of input radiation into a pump beam and first and second probe beams;
directing the pump beam through a vapor of an elemental material having a concentrated proportion of an isotope of the elemental material, the isotope having a known energy transition at a specified wavelength, along a first path in a first direction to saturate the material along the first path;
directing the first probe beam through the vapor of the elemental material along the first path in a second direction opposite the first direction;
directing the second probe beam through the vapor of the elemental material along a second path in the second direction;
receiving the first probe beam after the first probe beam has traversed the first path;
receiving the second probe beam after the second probe beam has traversed the second path;
measuring a spectral property of the first probe beam and a spectral property of the second probe beam as a wavelength of the beam of input radiation is varied though a range of wavelengths including the specified wavelength;
measuring a difference between the property of the first probe beam and the property of the second probe beam;
generating a transition profile based on a difference between the spectral property of the first probe beam and the spectral property of the second probe beam;
generating an absolute reference based at least in part on the transition profile; and calibrating a measurement of a spectral property of an excimer laser beam based at least in part on the absolute reference signal.

40. The system of clause 39 wherein at least 90% of the elemental material comprises the isotope.

41. A metrology method comprising:
performing a measurement of a center wavelength of a deep ultraviolet excimer laser beam;
generating an absolute wavelength reference using an elemental material having a concentrated proportion of an isotope of the elemental material, the isotope having a known energy transition at a specified wavelength; and
using the absolute wavelength reference to calibrate the measurement.

42. The method of clause 41 wherein the elemental material comprises at least 90% of the isotope.

43. A metrology method comprising:
performing a measurement of a bandwidth of a deep ultraviolet excimer laser beam;
generating an absolute bandwidth reference using an elemental material having a concentrated proportion of an isotope of the elemental material, the isotope having a known energy transition at a specified wavelength; and
using the absolute wavelength reference to calibrate the measurement.

44. The metrology method of clause 43 wherein the elemental material comprises at least 90% of the isotope.

45. A galvatron comprising an anode and a cathode, the cathode comprising an elemental material having a concentrated proportion of an isotope of the elemental material, the isotope having a known energy transition at a specified wavelength.

46. The galvatron of clause 45 wherein the elemental material comprises at least 90% of the isotope.

The above described implementations and other implementations are within the scope of the following claims.

1. A metrology system for measuring a spectral property of a beam of laser radiation, the metrology system comprising:
a beam separator for separating a beam of metrology radiation from the beam of laser radiation;
a source of a beam of calibration radiation;
a measuring module arranged to receive the beam of metrology radiation and configured to measure a spectral property of the beam of metrology radiation and generate a measurement signal indicative of the spectral property;
a calibration module arranged to receive either the beam of metrology radiation or the beam of calibration radiation as an input beam of radiation, the calibration module including
a material having an energy transition at a specified wavelength,
an optical arrangement configured to
divide the beam of input radiation into a pump beam and first and second probe beams,
direct the pump beam through the material along a first path in a first direction, and
direct the first probe beam through the material along the first path in a second direction opposite to the first direction and the second probe beam through the material along a second path in the second direction, and
a detector configured to
receive the first probe beam after the first probe beam has traversed the first path,
receive the second probe beam after the second probe beam has traversed the second path,
measure a property of the first probe beam and a property of the second probe beam, and
obtain a difference between the property of the first probe beam and the property of the second probe beam.

2. The metrology system of claim 1 further comprising a control system arranged to receive a differential signal and adapted to generate an absolute reference signal, wherein the control system is adapted to calibrate the measurement of the spectral property based on the absolute reference signal.

3. The metrology system of claim 1 wherein the pump beam saturates the material along the first path.

4. (canceled)

5. The metrology system of claim 1 wherein the spectral property includes at least one of a center wavelength of the beam of metrology radiation and a bandwidth of the beam of metrology radiation.

6. (canceled)

7. The metrology system of claim 1 wherein the material is platinum vapor.

8. The metrology system of claim 1 wherein the energy transition is the atomic absorption transition of platinum atoms at 193.4369 nanometers.

9. (canceled)

10. The metrology system of claim 1 wherein the optical arrangement comprises
a first beam splitter arranged to divide the first probe beam and second probe beam from the beam of input radiation and to direct the first probe beam along the first path and the second probe beam along the second path, and
a plurality of mirrors arranged to direct a remaining portion of the beam of input radiation after the first probe beam and second probe beam have been divided out along the first path in the first direction.

11. (canceled)

12. (canceled)

13. A metrology method comprising:
receiving a beam of input radiation;
dividing the beam of input radiation into a pump beam, a first probe beam, and a second probe beam;
directing the pump beam through a material having an energy transition at a specified wavelength along a first path in a first direction to saturate the material along the first path;
directing the first probe beam through the material along the first path in a second direction opposite to the first direction;
directing the second probe beam through the material along a second path in the second direction;
receiving the first probe beam after the first probe beam has traversed the first path;
receiving the second probe beam after the second probe beam has traversed the second path;
measuring a spectral property of the first probe beam and a spectral property of the second probe beam;
measuring a difference between the property of the first probe beam and the property of the second probe beam;
generating a transition profile based on a difference between the spectral property of the first probe beam and the spectral property of the second probe beam;
generating an absolute reference based at least in part on the transition profile; and
calibrating a measurement of a spectral property of a laser beam based at least in part on the absolute reference signal.

14. The metrology method of claim 13 wherein
the input radiation comprises either metrology radiation separated from a laser beam or calibration radiation from a calibration radiation source,
the transition profile is a convolved transition profile when the input radiation comprises the metrology radiation or an intrinsic transition profile when the input radiation comprises the calibration radiation, and
generating an absolute reference based at least in part on the transition profile comprises generating an absolute reference based at least in part on the convolved transition profile and the intrinsic transition profile.

15. The metrology method of claim 13 further comprising generating the input radiation using a single wavelength laser source.

16. The metrology method of claim 13 wherein the spectral property is a center wavelength of laser radiation or a bandwidth of laser radiation.

17. (canceled)

18. The metrology method of claim 13 wherein the material is platinum vapor or iron vapor.

19. (canceled)

20. (canceled)

21. (canceled)

22. (canceled)

23. (canceled)

24. A metrology system for measuring a spectral property of a beam of laser radiation, the metrology system comprising:
a beam separator for separating a beam of metrology radiation from the beam of laser radiation;
a source of a beam of calibration radiation;
a measuring module arranged to receive the beam of metrology radiation and configured to measure a spectral property of the beam of metrology radiation and generate a measurement signal indicative of the spectral property;
a calibration module arranged to receive either the beam of metrology radiation or the beam of calibration radiation as an input beam of radiation, the calibration module including
a vapor of an elemental material having a concentrated proportion of an isotope of the elemental material, the isotope having an energy transition at a specified wavelength,
an optical arrangement configured to
divide the beam of input radiation into a pump beam and first and second probe beams,
direct the pump beam through the material along a first path in a first direction, and
direct the first probe beam through the material along the first path in a second direction opposite to the first direction and the second probe beam through the material along a second path in the second direction, and
a detector configured to
receive the first probe beam after the first probe beam has traversed the first path,
receive the second probe beam after the second probe beam has traversed the second path,
measure a property of the first probe beam and a property of the second probe beam as a wavelength of the beam of input radiation is caused to vary through a range of wavelengths including the specified wavelength,
obtain a difference between the property of the first probe beam and the property of the second probe beam, and
generate a first differential signal based on the difference between the property of the first probe beam and the property of the second probe beam when the input beam comprises the beam of metrology radiation and a second differential signal based on the difference between the property of the first probe beam and the property of the second probe beam when the input beam comprises the beam of calibration radiation; and
a control system arranged to receive the first differential signal and the second differential signal and adapted to generate an absolute reference signal based on the first differential signal and the second differential signal.

25. The metrology system of claim 24 wherein the control system is adapted to calibrate the measurement of the spectral property based on the absolute reference signal.

26. The metrology system of claim 24 wherein the spectral property includes at least one of a center wavelength of the beam of metrology radiation and a bandwidth of the beam of metrology radiation.

27. (canceled)

28. The metrology system of claim 24 wherein the elemental material comprises at least one of platinum, iron, carbon, and arsenic.

29. (canceled)

30. (canceled)

31. (canceled)

32. The metrology system of claim 24 wherein at least 90% of the elemental material comprises the isotope.

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. The metrology system of claim 1, wherein the detector is further configured to generate a first differential signal based on a difference between the property of the first probe beam and the property of the second probe beam when the input beam comprises the beam of metrology radiation, and a second differential signal based on a difference between the property of the first probe beam and the property of the second probe beam when the input beam comprises the beam of calibration radiation.

48. The metrology system of claim 47, wherein the second probe beam has a Doppler line broadening and the first probe beam has a Doppler-free hole at a center of a Doppler broadened line.

49. The metrology method of claim 13, wherein the detector is further configured to recover a Doppler-free absorption line by removing a Doppler line broadening.
